(19) United States
(12) Patent Application Publication
(10) Pub. No.: US 2005/0237669 A1
(43) Pub. Date: Oct. 27, 2005

(54) Manufacturing method of thin-film magnetic head, thin-film magnetic head, head gimbal assembly with thin-film magnetic head, and magnetic disk apparatus with head gimbal assembly

(75) Inventor: Kunihiro Ueda, Hong Kong (CN)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: SAE Magnetics (H.K.) Ltd., Shatin (CN)

(21) Appl. No.: 11/102,931

(22) Filed: Apr. 11, 2005

(30) Foreign Application Priority Data
Apr. 23, 2004 (JP) 2004-128119

(51) Int. Cl. G11B 5/127; C23C 14/32

(52) U.S. Cl. 360/240; 204/192.32; 204/192.34; 360/110

(57) ABSTRACT

A manufacturing method of a thin-film magnetic head included a step of cutting a wafer on which a large number of thin-film magnetic head elements are formed into rowbars each of which has a plurality of aligned thin-film magnetic head elements, a step of cleaning, by an ion beam etching method, a surface of each of the cut rowbars, which is to be opposed to a magnetic recording medium, a step of depositing a protection film on the cleaned surface of the rowbar, and a step of separating thereafter the rowbar into individual thin-film magnetic heads.

### PRIORITY CLAIM

This application claims priority from Japanese patent application No. 2004-128119, filed on Apr. 23, 2004, which is incorporated herein by reference.

### BACKGROUND OF THE INVENTION

1. Field of the Invention

The present invention relates to a manufacturing method of a thin-film magnetic head that is usually provided with, for example, a giant magnetoresistive effect (GMR) head element or a tunnel magnetoresistive effect (TMR) head element, as a read magnetic head element, a thin-film magnetic head, a head gimbal assembly (HGA) provided with a thin-film magnetic head, and a magnetic disk device provided with an HGA.

2. Description of the Related Art

Usually, working processes performed after the wafer process of thin-film magnetic heads mainly consists of a cutting process of cutting the wafer into a plurality of bar members or rowbars, a lapping process of controlling the characteristics of the magnetic heads on each bar member, a touch lapping process of further finishing the condition of the lapped surface, a cleaning process of cleaning the lapped surface, a protection film formation process of forming a protection film on the cleaned surface, an air bearing surface (ABS) forming process of forming an ABS, and a head parting process of finally separating the bar members into individual magnetic heads.

In the cleaning process that is a pretreatment process of a protection film deposition, a sputter etching (SE) method is generally used. A typical SE method is disclosed in Japanese Patent Publication No. 09-274711-A2, in which a lapped surface of the substrate is sputtered by Ar ions with supplying power to the substrate to clean the lapped surface.

However, according to the cleaning treatment using the SE method described in the Japanese Patent Publication No. 09-274711-A2, only materials that are easily etched or have high etching rates are selectively sputter-etched but substrate materials or else that are not easily etched or have low etching rates are still remained. Thus, the amount of a pole tip recess (PTR) formed at the air-outflow edge or trailing edge of a magnetic head slider partially increases, causing a change in the shape of the PTR. If the cleaning treatment is early finished in order to keep the optimum shape of the PTR, the cleaning of the surface of the PTR may sometimes become insufficient. Therefore, corrosion resistance deteriorates when a protection film is formed on this insufficiently cleaned surface.

### BRIEF SUMMARY OF THE INVENTION

Therefore, it is an object of the present invention to provide a manufacturing method of a thin-film magnetic head whereby a thin-film magnetic head excellent in corrosion resistance can be obtained, to provide a thin-film magnetic head excellent in corrosion resistance, to provide an HGA with the thin-film magnetic head, and to provide a magnetic disk device with the HGA.

According to the present invention, a manufacturing method of a thin-film magnetic head includes a step of cutting a wafer on which a large number of thin-film magnetic head elements are formed into rowbars each of which has a plurality of aligned thin-film magnetic head elements, a step of cleaning, by an ion beam etching method, a surface of each of the cut rowbars, which is to be opposed to a magnetic recording medium, a step of depositing a protection film on the cleaned surface of the rowbar, and a step of separating thereafter the rowbar into individual thin-film magnetic heads.

By cleaning the surface of the rowbar using the IBE method in which the incident angle of beams is appropriately controlled, it is possible to hold etching selectivity at a low level. Thus, problems that only a part of materials are selectively etched causing partial increase in recess amount and change in the PTR shape never occurs. As a result, a cleaned surface can be obtained by performing sufficient cleaning and therefore, it is possible to form a protection film excellent in corrosion resistance.

It is preferred that the cleaning step includes performing the ion beam etching with an incident angle of ion beams equal to or more than 45 degrees but less than 85 degrees, more preferably with an incident angle of ion beams equal to or more than 50 degrees but equal to or less than 70 degrees. The incident angle described in this specification is an angle indicated as that a direction perpendicular to the plane surface of the substrate is 0 degree and that a direction parallel to the plane surface of the substrate is 90 degrees. According to the IBE method, as its characteristics, the closer to 0 degree the incident angle, the more selectively a metal material will be etched, and the closer to 90 degrees the incident angle, the more selectively an oxide material will be etched. If the incident angle is less than 45 degrees, a metal material will be etched deeper than necessary. If the incident angle is more than 85 degrees, the etching rate will decrease extremely, posing a problem in terms of productivity. More desirable cleaning effects are obtained when the incident angle of ion beams is equal to or more than 50 degrees but equal to or less than 70 degrees.

It is also preferred that the depositing step includes depositing an under layer first, and depositing a carbon layer on the deposited under layer. The adhesion of the carbon layer can be improved by adopting the double-layer structure of the under layer and the carbon layer.

It is also preferred that the depositing of the under layer includes depositing a layer containing silicon (Si). The adhesion of the carbon layer can be improved by using a under layer containing Si such as a layer made of Si, SiC or SiN_{X}.

It is preferred that the depositing of the under layer includes depositing the under layer by an ion beam deposition (IBD) method, a reactive sputter (RS) method or an electron cyclotron resonance (ECR) sputter method. A denser and thinner layer can be formed by using such film forming methods.

It is further preferred that the depositing step includes depositing only a carbon layer.

It is preferred that the depositing of the carbon layer comprises depositing a layer with a hydrogen content less than 25 atm %, more preferably with a hydrogen content less than 3 atm %. Good corrosion resistance can be obtained by forming a carbon layer having such hydrogen contents.

It is also preferred that the depositing of the carbon layer includes depositing the carbon layer by a cathodic arc (FCVA) method. According to the FCVA method, it is possible to form a thinner carbon layer having a low hydrogen content and hence a high purity.

According to the present invention, also, a thin-film magnetic head is fabricated by cutting a wafer on which a large number of thin-film magnetic head elements are formed into rowbars each of which has a plurality of aligned thin-film magnetic head elements, by cleaning, by an IBE method, a surface of each of the cut rowbars, which is to be opposed to a magnetic recording medium, by depositing a protection film on the cleaned surface of the rowbar, and by separating thereafter the rowbar. Further, according to the present invention, an HGA includes thus fabricated thin-film magnetic head, and a suspension for supporting the thin-film magnetic head. Still further, according to the present invention, a magnetic disk device includes a magnetic recording medium for recording magnetic information, thus assembled HGA, and means for moving the HGA above the magnetic recording medium.

Further objects and advantages of the present invention will be apparent from the following description of the preferred embodiments of the invention as illustrated in the accompanying drawings.

### BRIEF DESCRIPTION OF THE SEVERAL VIEWS OF THE DRAWINGS

FIG. 1 is a plan view schematically illustrating a constitution of a magnetic disk device as a preferred embodiment of the present invention;

FIG. 2 is a perspective view schematically illustrating a structure of a magnetic head slider in the embodiment of FIG. 1;

FIG. 3 is a sectional view taken along a line A-A of FIG. 2;

FIG. 4 is a sectional view taken along a line B-B of FIG. 2; and

FIG. 5 is a flowchart illustrating a part of processes of a manufacturing method of a thin-film magnetic head in the embodiment of FIG. 1.

### DETAILED DESCRIPTION OF THE INVENTION

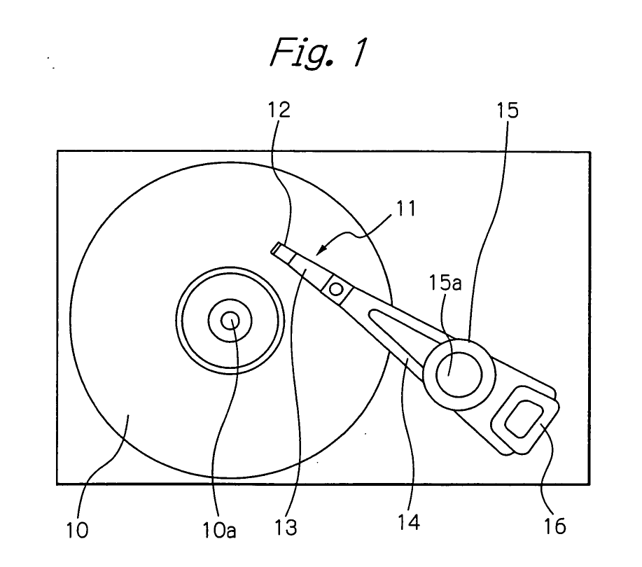

FIG. 1 schematically illustrates a constitution of a magnetic disk device as a preferred embodiment of the present invention.

In the figure, reference numeral 10 denotes one or more magnetic disks rotating in operation around a shaft 10a, and 11 denotes an HGA 11 having a magnetic head slider 12 and a suspension 13 that supports the magnetic head slider 12 at its top end section. The HGA 11 is attached to a top end section of a support arm 14. This support arm 14 is capable of rotating around a shaft 15a by a carriage 15. The carriage 15 is driven to rotate by an actuator of, for example, a voice coil motor (VCM). In the figure, reference numeral 16 denotes a driving coil of the VCM.

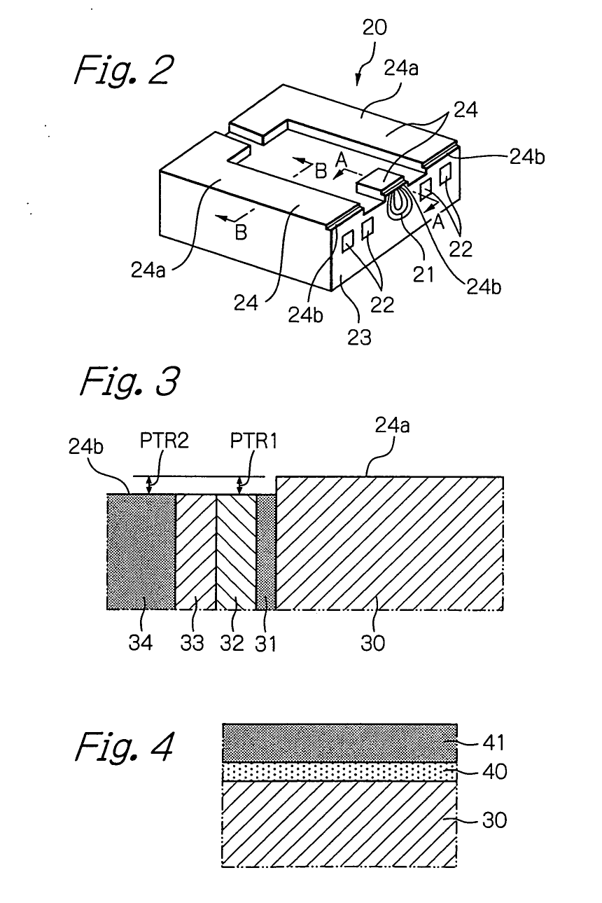

FIG. 2 schematically illustrates a structure of a magnetic head slider in the embodiment of FIG. 1, and FIGS. 3 and 4 are sectional views taken along a line A-A and a line B-B of FIG. 2.

As shown in FIG. 2, the magnetic head slider 12 (20) is provided with, on a surface at its air-outflow end side or trailing end surface 23, a thin-film magnetic head element 21 having, for example, a magnetoresistive effect (MR) read head element, such as a TMR head element or a GMR head element, and an inductive write head element, and terminal electrodes 22 of the thin-film magnetic head element 21. Rails 24 are formed on a surface of the magnetic head slider 20, which will be opposed to a magnetic recording medium. The surfaces of these rails 24 constitute ABSs 24a.

As shown in FIG. 3 although drawn in a little exaggerated manner, an end edge 24b of each rail 24 at the trailing end forms a pole tip recess (PTR) that backwards from the ABS 24a. By forming such PTR 24b, it is possible to avoid that the trailing edge of the magnetic head slider 20 during flying collides against the magnetic medium. In this figure, furthermore, reference numeral 30 denotes a substrate or wafer made of Al₂O₃—TiC for example, 31 denotes an element under layer for the thin-film magnetic head element 21, 32 denotes a lower shield layer, 33 denotes an upper shield layer, and 34 denotes an overcoat layer. It should be noted that illustration of other layers of the thin-film magnetic head element 21 are omitted in this figure.

As shown in FIG. 4, in this embodiment, an under layer 40 formed by a layer of Si, SiC or SiN_{X} (X=1.3 to 1.6) or a layer having a C—N bond (a layer of CN_{Y}, Y=1.3 to 1.5) is laminated on a side surface of the substrate 30, and a carbon layer 41 formed by a DLC (diamond like carbon) layer with a hydrogen content of less than 25 atm % is laminated on the under layer 40. The surface of the carbon layer 41 constitutes the ABS 24a that is the surface of the magnetic head slider 20 to be opposed to the magnetic recording medium. The under layer 40 and the carbon layer 41 constitute a protection film of the ABS side surface of the head slider with a thickness of 5 nm or less.

Because the protection film has a double-layer structure consisting of the under layer 40 and the carbon layer 41, sufficient corrosion resistance can be obtained even when the total film thickness is not more than 5 nm. This means that the carbon layer 41 can be formed with the thickness of less than 5 nm. The adhesion of the carbon layer 41 can be improved by using the layer made of Si, SiC or SiN_{X} or the layer made of CN_{X} as the under layer 40. By using the DLC layer with a hydrogen content of less than 3 atm % as the carbon layer 41, it is possible to obtain the protection film with good corrosion resistance even when the layer is thin.

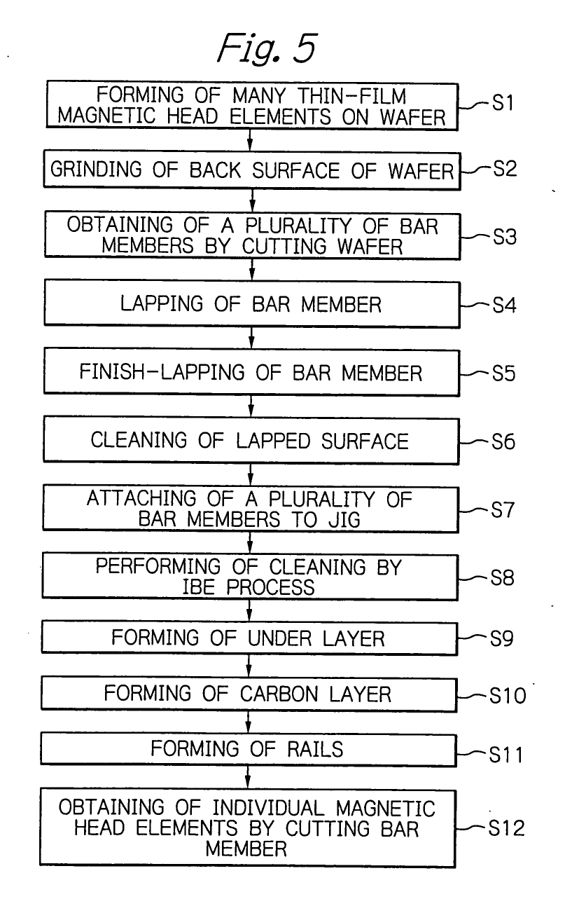

FIG. 5 illustrates a part of processes of a manufacturing method of a thin-film magnetic head in the embodiment of FIG. 1. The manufacturing method of the thin-film magnetic head in this embodiment will be described below with reference to this figure.

First, a wafer process is performed. In this wafer process, a large number of thin-film magnetic head elements provided with, for example, MR read head elements such as TMR head elements or GMR head elements, and inductive write head elements are formed on a wafer of Al₂O₃—TiC for example by using a thin-film technique (Step S1).

Thereafter, a working process is performed. In this working process, first, a back surface of the wafer that has many thin-film magnetic head elements formed on its front surface is ground to reduce the thickness of the wafer (Step S2).

Then, the thinned wafer is cut into a plurality of blocks and each of the blocks is further cut into a plurality of bar members or rowbars (Step S3). On each of the bar members, a plurality of the thin-film magnetic head elements are arranged in a row.

Then, each bar member is lapped in order to control the characteristics of the magnetic head element (Step S4). By this lapping, the MR heights of the respective MR read head elements on the bar member are adjusted by using RLGs (resistant lapping guides) or ELGs (electric lapping guides).

Subsequently, touch lapping is performed so as to adjust the crown or bending of the bar member and to further finish the condition of the lapped surface (Step S5).

Thereafter, the lapped surface is cleaned to remove contaminants (Step S6), and the plurality of cleaned bar members are mounted on a jig (Step S7). Then, these bar members are further cleaned by ion beam etching (IBE) process (Step S8).

This IBE has characteristics that the closer to 0 degree the incident angle of the ion beam, the more selectively a metal material will be etched, and that the closer to 90 degrees the incident angle of the ion beam, the more selectively an oxide material will be etched. Although there is an individual difference depending on an etching device used, it is desired that the incident angle of the ion beam be 45 degrees or more but less than 85 degrees. If the incident angle is less than 45 degrees, a metal material will be etched deeper than necessary. If the incident angle is larger than 85 degrees, the etching rate will extremely decrease causing poor productivity. More desirably, the incident angle of ion beam is 50 degrees or more but 70 degrees or less.

In the conventional cleaning process, the surface was cleaned by the sputter etching (SE) method. Contrary to this, in this embodiment, because the surface is cleaned by the IBE method while optimizing the incident angle of ion beams, it is possible to hold etching selectivity at a low level. As a result, only a part of materials can be selectively etched and hence a cleaned surface can be obtained by performing sufficient cleaning while controlling, for example, the PTR amount. Thanks for such cleaned surface, improved adhesion of the under layer can be expected. Therefore, sufficient protection effects can be obtained even if the protection film is thin.

After that, the under layer is deposited (Step S9). Because the carbon layer made of DCL has poor compatibility with metals, this under layer is interposed between the metal substrate and the carbon layer. Si is used as the material for the under layer. Although the sputter method is generally adopted for depositing the Si layer, the ion beam deposition (IBD) method is used in this embodiment. According to the IBD method, the deposition is performed by introducing an organic gas such as methane, ethane or ethylene gas in place of the argon (Ar) gas used in the IBE method, and by accelerating the ionized organic gas to the surface of the substrate in an electric field. Therefore, it is possible to deposit a closely packed film. The reactive sputter (RS) method or the ECR sputter method may be used in place of the IBD method. In place of Si, SiC or SiN_{X} (X=1.3 to 1.6, N is introduced during the deposition of Si and thereafter the compositions of Si and N are measured) or CN_{Y} having a C—N bond (Y=1.3 to 1.5, N is introduced during the deposition of C and thereafter the compositions of C and N are measured) may be deposited by the IBD method, the RS method or the ECR sputter method. As described above, by using the IBD method, higher energy deposition is attained and thus more closely packed and thinner film can be obtained.

Then, a carbon layer made of DLC is deposited (Step S10). Although the chemical vapor deposition (CVD) method is usually adopted as the method of depositing a DLC layer, the FCVA method is used in this embodiment. In the FCVA method, an arc is generated by using graphite as a main electrode to vaporize and ionize the graphite by the energy of the arc, and ions are induced to a deposition chamber by using an electromagnetic coil so as to perform deposition. Thus, it is possible to form a thinner carbon layer that hardly contains hydrogen (with a hydrogen content of less than 3 atm %). If it is allowed that the hydrogen content of the carbon layer is more than this value, the IBD method may be adopted. However, as will be described later, it is desired that the deposited DLC layer has a hydrogen content of less 25 atm %.

Thereafter, the formation of rails and patterning of ABSs are performed by performing photolithography and ion milling (RIE) (Step S11). Then, the bar member is cut and separated into individual magnetic head sliders (Step S12).

Various samples were prepared by changing the treatment conditions for the above-described cleaning process, deposition process of the under layer and the deposition process of the carbon layer, and corrosion test and measurement of the recessed amounts PTR1 and PTR2 were carried out. The conditions and results are shown in Table 1. These samples are GMR head elements of two bar members. As for the carbon layer, a DLC layer was used.

Also, for the sample 7 or a preferred sample of this embodiment and for the sample 17 or a comparative sample in which the SE method was used for the cleaning process, the corrosion tests were repeated under the same conditions. The results of this test are shown in Table 2. The corrosion tests were performed by immersing the bar members in an aqueous solution of sulfuric acid (pH 2) for five minutes. The number of sliders in which corrosion occurred was counted and the counted result was indicated by a corrosion rate. As for the measured values of recesses PTR1 and PTR2, as shown in FIG. 3, the backward distances from the ABS of the substrate 30 in the region of the lower shield layer 32 and the region of the overcoat layer 34 were measured by use of an atomic force microscope (AFM), respectively.

TABLE 1

| | | | | Thickness | Deposition | | Thickness | | PTR1 | PTR2 |
|---|---|---|---|---|---|---|---|---|---|---|
| | | Incident | | of Under | Method of | Hydrogen | of Carbon | Corrosion | Measured | Measured |
| Sample | Surface | Angle | Under | Layer | Carbon | Content | Layer | Test | value | value |
| No. | Treatment | (degree) | Layer | (Å) | Layer | (atm %) | (Å) | (%) | (nm) | (nm) |
| 1 | IBE | 40 | Si | 10 | FCVA | <3 | 20 | 10 | 4.0 | 1.0 |
| 2 | IBE | 45 | Si | 10 | FCVA | <3 | 20 | 3 | 2.5 | 1.2 |
| 3 | IBE | 50 | Si | 10 | FCVA | <3 | 20 | 1 | 1.5 | 1.2 |
| 4 | IBE | 55 | Si | 10 | FCVA | <3 | 20 | 1 | 1.2 | 1.2 |
| 5 | IBE | 60 | Si | 10 | FCVA | <3 | 20 | 1 | 1.2 | 2.0 |
| 6 | IBE | 70 | Si | 10 | FCVA | <3 | 20 | 3 | 1.0 | 2.5 |
| 7 | IBE | 80 | Si | 10 | FCVA | <3 | 20 | 5 | 1.0 | 3.0 |
| 8 | IBE | 85 | Si | 10 | FCVA | <3 | 20 | 8 | 0.5 | 3.2 |
| 9 | IBE | 88 | Si | 10 | FCVA | <3 | 20 | 10 | 0.5 | 3.3 |
| 10 | IBE | 55 | Si | 5 | FCVA | <3 | 10 | 4 | 1.2 | 1.2 |
| 11 | IBE | 55 | Si | 10 | FCVA | <3 | 10 | 3 | 1.2 | 1.2 |
| 12 | IBE | 55 | None | — | FCVA | <3 | 20 | 5 | 1.2 | 1.2 |
| 13 | IBE | 55 | Si | 10 | IBD | 15 | 20 | 3 | 1.2 | 1.2 |
| 14 | IBE | 55 | Si | 10 | IBD | 20 | 20 | 5 | 1.2 | 1.2 |
| 15 | IBE | 55 | Si | 10 | IBD | 25 | 20 | 6 | 1.2 | 1.2 |
| 16 | IBE | 55 | Si | 10 | IBD | 30 | 20 | 12 | 1.2 | 1.2 |
| 17 | SE | — | Si | 10 | FCVA | <3 | 20 | 13 | 1.2 | 2.5 |

TABLE 2

| Corrosion Test | Sample 4 | Sample 17 |
|---|---|---|
| First Time | 1% | 13% |
| Second Time | 2% | 8% |
| Third Time | 1% | 4% |
| Fourth Time | 1% | 10% |

As will be apparent from Table 2, by using the IBE method in the cleaning process, excellent corrosion test results with little scattering were obtained (the sample 4) in spite of the repeated test compared to the case where the SE method was adopted (the sample 17).

Furthermore, as will be apparent from Table 1, the corrosion test results were very poor when the incident angle of ion beams in the IBE method was 40 degrees (the sample 1) and when the incident angle was 85 degrees or more (the samples 8 and 9). However, when the incident angle was 45 degrees or more but less than 85 degrees (the samples 2 to 7), good test results were obtained. Furthermore, when the incident angle was 50 degrees or more but 70 degrees or less (the samples 3 to 6), not only good corrosion test results were obtained but also, at the same time, the difference between the measured values of recess PTR1 and PTR2 were small, maintaining good PTR shapes. Also, when the hydrogen content of the carbon layer was less than 25 atm %, the corrosion test results were good.

Although the protection film in the above-mentioned embodiment has a double-layer structure of the under layer and the carbon layer, a protection film with a single layer structure of the carbon layer with no under layer can be adopted in the present invention.

Many widely different embodiments of the present invention may be constructed without departing from the spirit and scope of the present invention. It should be understood that the present invention is not limited to the specific embodiments described in the specification, except as defined in the appended claims.

1. A manufacturing method of a thin-film magnetic head, comprising the steps of:
cutting a wafer on which a large number of thin-film magnetic head elements are formed into rowbars each of which has a plurality of aligned thin-film magnetic head elements;
cleaning, by an ion beam etching method, a surface of each of the cut rowbars, which is to be opposed to a magnetic recording medium;
depositing a protection film on the cleaned surface of the rowbar; and
separating thereafter the rowbar into individual thin-film magnetic heads.

2. The manufacturing method as claimed in claim 1, wherein said cleaning step comprises performing the ion beam etching with an incident angle of ion beams equal to or more than 45 degrees but less than 85 degrees.

3. The manufacturing method as claimed in claim 1, wherein said cleaning step comprises performing the ion beam etching with an incident angle of ion beams equal to or more than 50 degrees but equal to or less than 70 degrees.

4. The manufacturing method as claimed in claim 1, wherein said depositing step comprises depositing an under layer first, and depositing a carbon layer on the deposited under layer.

5. The manufacturing method as claimed in claim 4, wherein said depositing of the under layer comprises depositing a layer containing silicon.

6. The manufacturing method as claimed in claim 4, wherein said depositing of the under layer comprises depositing the under layer by an ion beam deposition method, a reactive sputter method or an electron cyclotron resonance sputter method.

7. The manufacturing method as claimed in claim 1, wherein said depositing step comprises depositing only a carbon layer.

8. The manufacturing method as claimed in claim 4, wherein said depositing of the carbon layer comprises depositing a layer with a hydrogen content less than 25 atm %.

9. The manufacturing method as claimed in claim 4, wherein said depositing of the carbon layer comprises depositing a layer with a hydrogen content less than 3 atm %.

10. The manufacturing method as claimed in claim 4, wherein said depositing of the carbon layer comprises depositing the carbon layer by a cathodic arc method.

11. A thin-film magnetic head being fabricated by cutting a wafer on which a large number of thin-film magnetic head elements are formed into rowbars each of which has a plurality of aligned thin-film magnetic head elements, by cleaning, by an ion beam etching method, a surface of each of the cut rowbars, which is to be opposed to a magnetic recording medium, by depositing a protection film on the cleaned surface of the rowbar, and by separating thereafter the rowbar.

12. A head gimbal assembly, comprising:
a thin-film magnetic head fabricated by cutting a wafer on which a large number of thin-film magnetic head elements are formed into rowbars each of which has a plurality of aligned thin-film magnetic head elements, by cleaning, by an ion beam etching method, a surface of each of the cut rowbars, which is to be opposed to a magnetic recording medium, by depositing a protection film on the cleaned surface of the rowbar, and by separating thereafter the rowbar; and
a suspension for supporting the thin-film magnetic head.

13. A magnetic disk device, comprising:
a magnetic recording medium for recording magnetic information;
a head gimbal assembly provided with a thin-film magnetic head fabricated by cutting a wafer on which a large number of thin-film magnetic head elements are formed into rowbars each of which has a plurality of aligned thin-film magnetic head elements, by cleaning, by an ion beam etching method, a surface of each of the cut rowbars, which is to be opposed to a magnetic recording medium, by depositing a protection film on the cleaned surface of the rowbar, and by separating thereafter the rowbar, and a suspension for supporting the thin-film magnetic head; and
means for moving the head gimbal assembly above the magnetic recording medium.
